(19) United States
(12) Patent Application Publication
(10) Pub. No.: US 2024/0188420 A1
(43) Pub. Date: Jun. 6, 2024

(54) Environment-Friendly Tin Perovskite Solar Cells and Methods for Preparing the Same

(71) Applicant: City University of Hong Kong, Kowloon (HK)

(72) Inventors: Zonglong Zhu, Kowloon (HK); Bo Li, Kowloon (HK); Xin WU, Kowloon (HK)

(21) Appl. No.: 17/991,165

(22) Filed: Nov. 21, 2022

(51) Int. Cl. H10K 85/50; H10K 30/50; H10K 71/12; H10K 85/20; H10K 85/60

(52) U.S. Cl. CPC H10K 85/50; H10K 30/50; H10K 71/12; H10K 85/211; H10K 85/654; H10K 85/6572

(57) ABSTRACT

A tin-based perovskite solar cell (PVSC) includes a surface treatment layer containing a functionalized fullerene derivative having a structure of Formula I below, in which R is a monocyclic or polycyclic aromatic ring including one or two nitrogen atoms. A process of preparing a tin-based PVSC includes the steps of: providing a substrate; coating a hole transport layer onto the substrate; and preparing a perovskite layer including the step of coating a perovskite precursor solution containing a tin-based perovskite composition onto the hole transport layer, in which the tin-based perovskite composition has the empirical formula: CsₓEDA_{y}FA_{1-x-2y}SnI₃, where x is from about 0 to about 0.12; y is from about 0.01 to about 0.03; FA is formamidinium; and EDA is ethylenediamine.

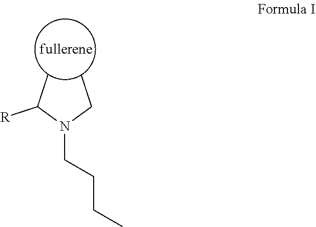

### STATEMENT REGARDING FEDERALLY SPONSORED RESEARCH

This invention was supported by the Hong Kong Innovation and Technology Support Program (ITS/095/20).

### FIELD OF THE INVENTION

The invention relates to perovskite solar cells and more particularly to lead-free perovskite solar cells.

### BACKGROUND

Organic-inorganic lead halide perovskites have made tremendous development owing to their remarkable optoelectronic properties, low-cost solution processing, and exceptional power conversion efficiency (PCE). However, the perceived toxicity of lead in the state-of-the-art perovskite solar cells (PVSCs) remains an issue that must be addressed on the path towards commercialization. As an alternative to lead halide perovskites, tin perovskites outperform other lead-free perovskite candidates due to a favorable band gap, low exciton-bind energy, and high carrier mobility. Despite the rapid development of tin PVSCs, there is still a substantial efficiency difference between tin and lead perovskite photovoltaics, leading to a massive energy loss. Therefore, it is critical to develop effective strategies to reduce the energy loss of environment-friendly tin PVSCs.

Long-term stability of tin PVSCs is another challenging issue to the commercialization. As such, it is desirable to develop new tin PVSCs with both improved PCE and stability.

### SUMMARY OF THE INVENTION

An embodiment of the present invention relates to a tin-based perovskite solar cell (PVSC) including a surface treatment layer containing a functionalized fullerene derivative having a structure of formula I below:

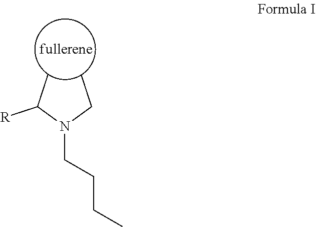

in which R is a monocyclic or polycyclic aromatic ring including one or two nitrogen atoms.

An embodiment of the present invention relates to a process of preparing a tin-based PVSC including the steps of:
providing a substrate;
coating a hole transport layer onto the substrate; and
preparing a perovskite layer including the step of coating a perovskite precursor solution containing a tin-based perovskite composition onto the hole transport layer , in which the tin-based perovskite composition has the empirical formula: CsₓEDA_{y}FA_{1-x-2y}SnI₃
   in which x is from about 0 to about 0.12;
   in which y is from about 0.01 to about 0.03;
   in which FA is formamidinium; and
   in which EDA is ethylenediamine.

Without intending to be limited by theory, it is believed that the present invention may provide one or more benefits such as the tin-based PVSCs have high-efficiency and exhibit more stable performances.

### BRIEF DESCRIPTION OF THE DRAWINGS

FIG. 1 shows an embodiment of UV-vis absorption spectrum of pristine FA_{0.96}EDA_{0.02}SnI₃ perovskite film;

FIG. 2 shows an embodiment of Tauc plot of pristine FA_{0.96}EDA_{0.02}SnI₃ perovskite film;

FIG. 3 shows a SEM image of pristine FA_{0.96}EDA_{0.02}SnI₃ perovskite film;

FIG. 4 shows an embodiment of comparison of the carrier mobility of FASnI₃, PEA_{0.15}FA_{0.85}SnI₃, and FA_{0.96}EDA_{0.02}SnI₃ perovskite films;

FIG. 5a shows an embodiment of schematic illustration of a PVSC including: 1—substrate layer, 20—hole transport layers, 30—perovskite layer, 40—surface treatment layer, 50—electron transport layers, and 60—metal electrode;

FIG. 5b shows an embodiment of schematic illustration of the device configuration of the C₆₀-BPy interface modified tin PVSCs and the corresponding C₆₀-BPy molecule structures;
FIG. 6 shows an embodiment of XPS characterization of Sn element in FA_{0.96}EDA_{0.02}SnI₃ PVSC modified with 1.0 mg/mL C₆₀-BPy;

FIG. 7 shows an embodiment of XPS characterization of I element in FA_{0.96}EDA_{0.02}SnI₃ PVSC modified with 1.0 mg/mL C₆₀-BPy;

FIG. 8 shows an embodiment of FTIR characterization of the pristine C₆₀-Bpy and perovskite-C₆₀-Bpy;

FIG. 9 shows an embodiment of XRD patterns of the FA_{0.96}EDA_{0.02}SnI₃ perovskite films with and without C₆₀-Bpy;

FIG. 10 shows an embodiment of Space Charge Limit Current Model (SCLC) plots of the FA_{0.96}EDA_{0.02}SnI₃ perovskite films with and without C₆₀-Bpy based on a hole-only device (ITO/PEDOT:PSS/perovskite/MoO₃/Ag);

FIG. 11 shows an embodiment of SCLC plots of the FA_{0.96}EDA_{0.02}SnI₃ perovskite films with and without C₆₀-Bpy based on an electron-only device (ITO/TiO₂/perovskite/C_{60/}Ag);

FIG. 12 shows an embodiment of Urbach energy plots of the FA_{0.96}EDA_{0.02}SnI₃ perovskite films with and without C₆₀-Bpy;

FIG. 13 shows an embodiment of V_{OC} vs light intensity of the FA_{0.96}EDA_{0.02}SnI₃ perovskite films with and without C₆₀-Bpy;

FIG. 14 shows an AFM image of the pristine FA_{0.96}EDA_{0.02}SnI₃ perovskite film;

FIG. 15 shows an AFM image of the FA_{0.96}EDA_{0.02}SnI₃ perovskite film with C₆₀-BPy;

FIG. 16 shows a KPFM image of the pristine FA_{0.96}EDA_{0.02}SnI₃ perovskite film;

FIG. 17 shows a KPFM image of the FA_{0.96}EDA_{0.02}SnI₃ perovskite film with C₆₀-BPy;

FIG. 18 shows an embodiment of surface potential statistics of the pristine FA0.96EDAo.o2SnI3 perovskite film;

FIG. 19 shows an embodiment of surface potential statistics of the FA_{0.96}EDA_{0.02}SnI₃ perovskite film with C₆₀-BPy;

FIG. 20 shows an embodiment of steady-state PL spectra of the perovskite/ETL and perovskite/C₆₀-BPy/ETL;

FIG. 21 shows an embodiment of time-resolved PL spectra of the perovskite/ETL and perovskite/C₆₀-BPy/ETL;

FIG. 22 shows an embodiment of schematic illustration of the interface energy band evolution and charge carrier dynamics under illumination;

FIG. 23 shows an embodiment of statistics of the photovoltaic parameters distribution of the FA_{0.96}EDA_{0.02}SnI₃ PVSCs modified with different concentrations of C₆₀-BPy;

FIG. 24 shows an embodiment of J-V curve of the best performing FA_{0.96}EDA_{0.02}SnI₃ PVSCs modified with 1.0 mg/mL C₆₀-BPy;

FIG. 25 shows an embodiment of EQE curve and corresponding integrated current of the best performing FA_{0.96}EDA_{0.02}SnI₃ PVSC modified with 1.0 mg/mL C₆₀-BPy;

FIG. 26 shows an embodiment of stabilized current and PCE curves of the best performing FA_{0.96}EDA_{0.02}SnI₃ PVSC with 1.0 mg/mL C₆₀-BPy measured under continuous illumination;

FIG. 27 shows an embodiment of PCE evolution of the control and C₆₀-BPy modified FA_{0.96}EDA_{0.02}SnI₃ PVSCs under AM 1.5 G light illumination stored in N₂ atmosphere;

FIG. 28 shows an embodiment of PCE evolution of the control and C₆₀-BPy modified FA_{0.96}EDA_{0.02}SnI₃ PVSCs under heating at 80° C. in N₂ atmosphere; and

FIG. 29 shows an embodiment of the statistics of the normalized efficiencies for tin PVSCs with or without C₆₀-BPy, and lead PVSCs with or without C₆₀-BPy.

The figures herein are for illustrative purposes only and are not necessarily drawn to scale.

### DESCRIPTION OF THE PREFERRED EMBODIMENTS

Unless otherwise specifically provided, all tests herein are conducted at standard conditions which include a room and testing temperature of 25° C., sea level (1 atm.) pressure, pH 7, and all measurements are made in metric units. Furthermore, all percentages, ratios, etc. herein are by weight, unless specifically indicated otherwise. It is understood that unless otherwise specifically noted, the materials compounds, chemicals, etc. described herein are typically commodity items and/or industry-standard items available from a variety of suppliers worldwide.

As used herein, “ITO” refers to Indium Tin Oxide, “PEN” refers to Polyethylene Naphthalate, “PET” refers to Polyethylene Terephthalate, and “FTO” refers to Fluorine-doped Tin Oxide.

As used herein, a single dash, “−”, or a double dash, “=”, may be used before and/or after terms to indicate the bond order of the bond between the stated substituent and its parent moiety. A single dash represents a single bond, while a double dash represents a double bond. In the absence of a single or double dash, it is assumed that the substituent and its parent moiety form a single bond. Furthermore, unless a dash indicates otherwise, substituents are to be read “left to right.”

As used herein, band gap or band gap energy (E_{G}) refers to the minimum amount of energy required for an electron to break free of its bound state.

### 1. Functionalized Fullerene Derivative

An embodiment of the present invention relates to a functionalized fullerene derivative having a structure of Formula I below:

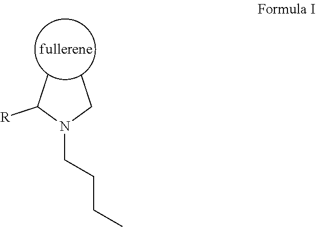

in which R is a monocyclic or polycyclic aromatic ring comprising one or two nitrogen atoms.

Without intending to be limited by theory it is belived that the interface functionalization using the fullerene derivatives can strongly anchor on the perovskite surface via coordination interactions between the functionalizing moiety on the derivatives and the Sn²⁺ ion, which not only passivates the perovskite surface defects, but also regulates the interface energy level alignment to reduce non-radiative recombination.

In some embodiments, R in Formula I is a monocyclic aromatic ring selected from the group of pyrazine, pyridine, and a combination thereof. In some embodiments, R is not pyridine. In an embodiment herein, the monocyclic aromatic ring is preferably pyridine because it can form strong binding with Pb ions in perovskite, which can passivate Pb related defects.

In some embodiments, R in Formula I is a polycyclic aromatic ring selected from the group of isoquinoline, naphthyridine, and a combination thereof.

In some embodiments, the functionalized fullerene derivative has a structure selected from the group of:

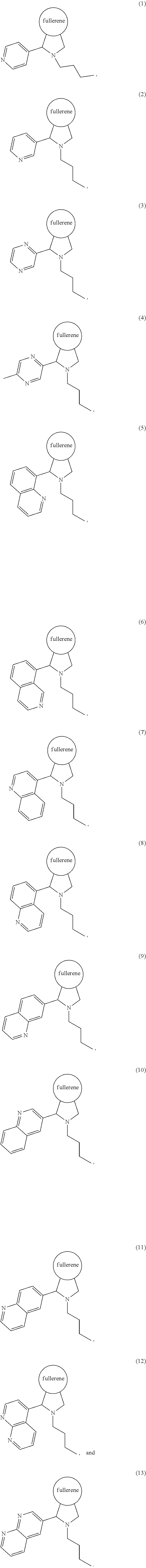

In some embodiments, the functionalized fullerene derivative has a structure selected from any of formulae (3) to (13) as listed above. In some embodiments, the functionalized fullerene derivative has a structure of formula (1), which also referred to as C₆₀-BPy herein. Without being limited by alkyl chain. Pyridine can better combine fullerene molecules with tin-based perovskites and improve their mutual binding force. Furthermore, it is believed that long alkyl chains can increase the robustness of perovskite films, thereby improving device reliability.

An embodiment of the present invention relates to a process of preparing the functionalized fullerene derivative described above, which includes the following steps:
adding N-butyl glycine (about 0.006˜0.024 mol/L, preferably about 0.016 mol/L) and a precursor compound to a solution of fullerene (C₆₀; about 0.003˜0.012 mol/L, preferably about 0.008 mol/L) in chlorobenzene with a molar ratio of N-butyl glycine to C₆₀ being about 2:1;
heating the mixture at about 65˜95° C. (preferably 80° C.) under a nitrogen atmosphere for about 5 h; and
removing the solution.

Without being bonding to theory, it is believed that the materials synthesized within the above-mentioned parameters have higher purity and better stability. If the ratio of N-butyl glycine to C₆₀ does not conform to 2:1, it will lead to the increase of impurities and the decrease of synthesis yield. If the material concentration is too high or the mixture is heated at a higher temperature than the above, the reaction rate may be too fast, resulting in agglomeration of the synthesis product, which is not conducive to later use.

In some embodiments, the precursor compound is selected from the group of n-butyl-pyridine, 4-pyridinecarboxaldehyde, nicotinaldehyde, pyrazine-2-carbaldehyde, 5-methylpyrazine-2-carbaldehyde, quinoline-8-carbaldehyde, is oquinoline-8-carbaldehyde, quinoline-4-carbaldehyde, quinoline-5-carbaldehyde, quinoline-7-carbaldehyde, quinoline-3-carbaldehyde, quinoline-6-carbaldehyde, 1,8-naphthyridine-4-carbaldehyde, and 1,8-naphthyridine-3-carbaldehyde. In an embodiment herein, the precursor compound is preferably n-butyl-pyridine.

In some embodiments, the mixture is monitored by thin layer chromatography during the heating step. In some embodiments, the removing of the solution is performed after cooling to room temperature and under reduced pressure. In some embodiments, the process further comprise the step of purifying the resulted product via silica gel column chromatography.

### 2. Perovskite Composition

An embodiment of the present invention relates to a tin-based perovskite composition having the empirical formula: CsₓEDA_{y}FA_{1-x-2y}SnI₃, in which x is from about 0 to about 0.12; y is from about 0.01 to about 0.03; FA is formamidinium; and EDA is ethylenediamine. For example, in the empirical formula, x may be about 0, and y may be about 0.02.

In some embodiments, the tin-based perovskite composition has any of the following empirical formulae: FA_{0.96}EDA_{0.02}SnI₃ ; Cs_{0.12}EDA_{0.03}FA_{0.82}SnI₃; EDA_{0.01}FA_{0.098}SnI₃; and Cs_{0.06}EDA_{0.015}FA_{0.91}SnI₃.

Without intending to be limited by theory it is believed that the tin-based perovskite composition of this invention contains EDA²⁺ ions, which can better stabilize the tin-based perovskite crystal structure and improve the stability of tin-based perovskite devices, compared with traditional tin-based perovskite (CsₓFA₁₋ₓPbI₃).

An embodiment of the present invention relates to a process of preparing a perovskite precursor solution, which includes the following steps:
mixing SnI₂, FAI, CsI and EDADI in DMF:DMSO mixed solvent in certain amount to meet the empirical formula of CsₓEDA_{y}FA_{1-x-2y}SnI₃ (where x is about 0˜0.12, and y is about 0.010.03); and
stirring the perovskite precursor solution.

In some embodiments, about 0.85 M to about 1.0 M perovskite precursor solution is prepared by mix the raw materials in 1 mL DMF:DMSO (about 3:1 to 5:1 /v:v) mixed solvent. In some embodiments, about 10 mol % to about 15 mol % of excess SnF₂ and about 20 mg to about 30 mg Sn powder is added into the solution to suppress the Sn oxidation. The solution is stirred at room temperature for about 6 h to about 10 h and is filtered through a 0.45 μm filter before use.

### 3. Perovskite Solar Cell (PVSC)

An embodiment of the present invention relates to a perovskite solar cell, in particular an inverted perovskite solar cell, including a surface treatment layer containing a a functionalized fullerene derivative having a structure of Formula I described herein.

Among perovskite solar cells (PVSCs), it is believed that inverted (p-n/p-i-n structure) devices have typically exhibited more stable behaviour than conventional (n-p/n-i-p) PVSCs, due in part to their non-doped hole transporting materials and highly crystalline perovskite films. The following description is with primary reference to inverted PVSCs, but the beneficial effects of an interface layer (i.e., a surface treatment layer described herein after) as described herein apply equally to a conventional PVSC structure.

### Substrate

In some embodiments, the perovskite solar cell includes a substrate, which forms the base or support for the solar cell structure. Visible light (such as incident sunlight) enters the solar cell through the substrate.

In some embodiment, the substrate is transparent and may be formed of glass, or any other suitable transparent material. In some embodiments, the substrate includes a material selected from the group of ITO/Glass, ITO/PEN, ITO/PET, FTO/Glass, FTO/PEN, FTO/PET, and a combination thereof. In an embodiment herein, the substrate is preferably ITO. Compared with PEN and PET, ITO substrate has higher transmittance and higher device efficiency. Compared with FTO, it is believed that ITO-based devices are thinner and lighter, making it easier to transport and install.

### Perovskite Layer

In some embodiments, the perovskite solar cell includes a perovskite layer, which is the active or functional layer of the solar cell. In other words, the perovskite layer is the light-absorbing layer of the solar cell. The term light-absorbing' in relation to the perovskite(s) (and by extension the perovskite layer 30 comprising one or more perovskites) refers to its role in absorbing light, e.g. visible light, so as to act as a light absorbing material which allows to convert the light into electrical energy. A perovskite type compound exhibits strong absorption with respect to visible light incident on the solar cell, and the bandgap of a perovskite semiconductor can be tuned to a desired band gap energy (E_{G}), thereby improving the efficiency of such solar cells.

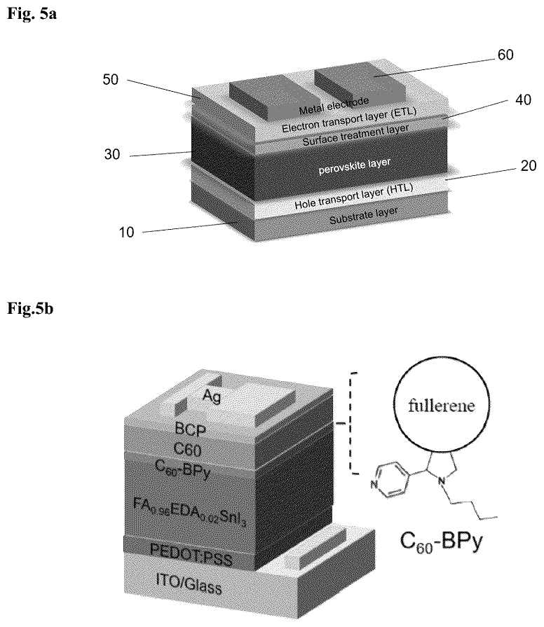

As in the exemplar solar cell depicted in FIG. 5a, solar radiation or visible light passes through the substrate 10 into the perovskite layer 30, whereupon at least a portion of the solar radiation is absorbed by exciting an electron across a semiconductor band gap so as to enable electrical generation. In particular, the electron is excited from a valence band of the semiconductor, across the bandgap, to a conduction band. The excited electron sits in the conduction band, and a corresponding hole (a vacancy or absence of an electron, rather than a physical particle in and of itself) remains in the valence band of the semiconductor.

It is believed that an asymmetry within the perovskite layer acts to separate the excited electron away from the hole, moving the charge carriers (holes and electrons) away from the point of electron promotion for collection and current generation. In the examples described herein, this asymmetry is provided by a junction within the perovskite solar cell (such as an n-p or n-i-p junction for solar cell, or a p-n or p-i-n junction for inverted solar cell). In other words, the perovskite solar cell can include any suitable semiconductor junction.

In some embodiments, the perovskite layer can include one or more heterojunctions. Heterojunctions can be formed within the perovskite layer by way of two different, undoped, perovskite materials. Thus, the perovskites referred to herein may both be undoped semiconductors. Alternatively, the perovskite may be doped with p-type or n-type dopants to form a junction. In other words, they may be doped (throughout and/or at the surface) with at least one dopant material of greater valence than the bulk material (to provide n-type doping) and/or may be doped with at least one dopant material of lower valence than the bulk material (to give p-type doping). N-type doping will tend to increase the n-type character of the semiconductor material, while p-type doping will tend to reduce the degree of the natural n-type state (e.g. due to defects). Such doping may be made with any suitable material including F, Sb, N, Ge, Si, C, In, InO and/or Al. Suitable dopants and doping levels will be evident to those of skill in the art.

In some embodiments, the light-absorbing perovskite layer comprises one or more metal halide perovskites. For example, the metal halide perovskites may have a structure of ABX₃, where the A-site ions can be selected from the group of FA⁺, MA⁺, Cs⁺, and Rb⁺, and B-site ions can be selected from the group of Pb²⁺, Sn²⁺, Bi⁺, and Ag⁺, and X-site ions can be selected from the group of F⁻, Cl⁻, Br⁻, and I⁻. In some examples, the light-absorbing perovskite layer may comprise two different metal halide perovskites configured to form a semiconductor heterojunction within the perovskite layer. Any perovskite capable of performing the desired light-absorbing and charge separation functions may be used in the light-absorbing perovskite layer.

### Hole Transport Layer (HTL)

In some embodiment, the solar cell may further includes a hole transport layer (i.e., p-type charge-extraction layer) comprising or consisting of one or more hole transport materials. In an inverted PVSC, for example, as shown in FIG. 5a, the HTL (the hole transport layer 20) is located proximate to the transparent substrate 10 (holes are collected at the electrode proximate the substrate, converse to the conventional PVSC).

Any hole-transport material known to the skilled person may be used. Example hole transport materials include but is not limited to organic hole-transport materials, inorganic hole-transport materials or combinations thereof. Organic hole-transport materials may be polymeric or non-polymeric. Exemplary polymeric hole-transport materials include polythiophenes, for example poly (3-hexylthiophene) (P3HT); p oly (arylamines) for example Poly [bis(4-phenyl)(2,4,6-trimethylphenyl)amine (PTAA); and doped PEDOT, for example Poly(3,4-ethylenedioxythiophene): poly(styrene sulfonate) (PEDOT:PSS). Exemplary non-polymeric organic hole-transport materials are compounds containing one or more arylamine groups, for example spiro-OMeTAD. Examplary inorganic hole-transport materials include copper-based materials (e.g. Cuac, CuSCN, CuI, etc.), nickel-based materials (e.g. NiOₓ), two-dimensional layered materials such as chalcogens (e.g. MoS₂, WS₂, etc.). Hole transport materials encourage a flow of holes from the p-type perovskite, away from the junction within the perovskite layer, while block the movement of electrons.

In some embodiments, the hole transport layer includes a material selected from the group of PEDOT:PSS, PTAA, and a combination thereof. It is believed that, these materials with excellent hole transport ability are also mature commercial hole transport materials, and therefore are readily available for industrial production.

### Electron Transport Layer (ETL)

In some embodiments, the solar cell may further includes an electron transport layer (i.e., n-type charge-extraction layer). The ETL comprises an electron transport material. Any electron transport material known to the skilled person may be used. The ETL may comprise or consist of an organic electron transport material, an inorganic electron transport material or mixtures thereof. Example electron transport materials include organic materials such as fullerenes, for example C₆₀ or Phenyl-C₆₁-butyric acid methyl ester (PC₆₁BM), metal oxides such as TiO₂, ZnO, SnO₂. Electron transport materials may encourage a flow of electrons from the n-type perovskite, away from the junction within the perovskite layer 30, while blocking the movement of holes. In this way, electrons accumulate at electron transport layer 50. In use, the electron transport layer 50 is negatively charged due to the accumulation of electrons. When the solar cell is connected to an external load, the electrons leave the solar cell via the electron transport layer 50.

In some embodiments, the electron transport layer includes a material selected from the group of fullerene C₆₀, TiO₂, SnO₂, Al₂O₃, PC₆₁BM, Phenyl-C₇₂-butyric acid methyl ester (PC₇₂BM), and a combination thereof. In an embodiment herein, the electron transport layer preferably includes PC₆₁BM. Without being bound to theory, it is believed that PC₆₁BM can passivate the defects in the perovskite functional layer and at the interface, and improve the photoelectric conversion efficiency of the solar cell device. The PCBM interface modification layer is introduced to modify the interface at the electron transport layer/perovskite layer to improve the optoelectronic performance of the solar cell device. It is believed that the PCBM interface modification cannot completely eliminate the hysteresis effect of the solar cell, so this invention dopes the PCBM material into the photovoltaic functional layer of the solar cell device to study the effect of the grain boundary gap on the solar cell performance.

### Metal Electrode

In some embodiments, the solar cell may further includes a metal electrode. In some embodiments, the metal electrode is selected from the group of Ag, Au, Al, Cu and a combination thereof. In an embodiment herein, the metal electrode is preferably Ag or Au. In some embodiments, carbon can also be used as the electrode of the solar cell.

### Tin-Based PVSC Structures

In some embodiments, the above-described perovskite solar cell may be a tin-based perovskite solar cell (PVSC).

In some embodiments, the tin-based PVSC includes a perovskite layer containing a tin-based perovskite composition having the empirical formula CSₓEDA_{y}FA_{1-x-2y}SnI₃ as defined herein.

Without intending to be limited by theory it is belived that the present inveniton develops a synergistic strategy combining component optimization, crystallization regulation and interface functionalization to fabricate the high-efficiency and stable lead-free tin PVSCs. The component and crystallization manipulation can decrease the bulk defect density and suppresses the tin oxidation. In addition, it is believed that the fullerene derivatives such fullerene-n-butyl-pyridine (C₆₀-BPy) according to the invention, as an interface functionalization material, simultaneously enhance the efficiency and stability of tin PVSCs.

In some embodiments, the surface treatment layer is in contact with one side of the perovskite layer.

In some embodiments, the tin-based PVSC according to the invention has a PCE of about 12.5% to about 14.5%. For example, the resulting devices according to the invention can achieve a PCE of about 14.14% with negligible hysteresis. In some embodiments, the tin-based PVSC according to the invention maintains over about 95% of their initial PCE under continuous one-sun illumination for about 1000 hours.

In some embodiments, the tin-based PVSC according to the invention further includes the following layers:
a substrate;
optionally a first charge-extraction layer between the substrate and the perovskite layer;
optionally a second charge-extraction layer on the surface treatment layer; and
a metal electrode on the second charge-extraction layer,
wherein each of the first charge-extraction layer and the second charge-extraction layer
could be either a hole transport layer or an electron transport layer.

In some embodiments, the tin-based PVSC according to the invention includes the hole transport layer, the electron transport layer, or the combination thereof. In some embodiment, the tin-based PVSC does not include the hole transport layer or the electron transport layer. In some embodiments, the tin-based PVSC according to the invention has any of the following structures: electrode/HTM/perovskite/ETL/substrate, electrode/ETL/perovskite/HTM/substrate, electrode/HTM/perovskite/substrate, electrode/perovskite/ETL/substrate, in which the perovskite is covered by the surface treatment layer.

In some embodiments, the tin-based PVSC according to the invention further includes the following layers:
a substrate;
a hole transport layer between the substrate and the perovskite layer;
an electron transport layer on the surface treatment layer; and
a metal electrode on the electron transport layer.

In the PVSCs, the functional or active perovskite layer are sandwiched between the HTL and ETL. In other words, the charge transporting layers are deposited on the top and the bottom sides of the perovskite active layer, respectively. The charge carriers are extracted at the HTL/perovskite and perovskite/ETL interfaces and collected through the respective conductors/contacts. During this process, the carrier charges may be subject to recombination, for example due to any interfacial defects and associated specific charge distributions.

Without intending to be limited by theory it is believed that interface recombination arises from charge dynamics at the interface (including charge extraction, charge transfer, and charge recombination). The imperfect interfacial structural and electronic mismatches usually act as energy barriers for charge transport and charge recombination. Furthermore, it is believed that defects at the surface and interface of polycrystalline perovskite films are mostly either positively charged or negatively charged. Trap states at the perovskite surface and interfaces can lead to charge accumulation and recombination losses in the device.

In some embodiment, the surface treatment layer is inserted between the perovskite layer and the electron transport layer. It has been surprisingly found that the performance of the perovskite solar cell described herein can be improved when the surface treatment layer comprising an interfacial compound (i.e., the functionalized fullerene derivative) as described herein is provided between the electron transport layer and the perovskite layer. It is believed that such surface treatment layer can suppress defects in the perovskite surface and minimize interfacial non-radiative combination losses. In this way, the surface treatment layer improves the extraction of electrons at the perovskite interface, increases the efficiency of the solar cell, and improves the stability of the solar cell.

In some embodiments, the surface treatment layer interfaces directly with the perovskite layer. In other words, the surface treatment layer and the perovskite layer are in direct contact. The surface treatment layer can be deposited directly on the active perovskite layer, as described below, or may be otherwise formed.

The above-mentioned definitions and descriptions regarding the substrate, the hole transport layer, the perovskite layer, and the electron transport layer also apply to the Tin-based PVSC structures herein.

In certain embodiments, the PVSC structure of the present application includes: a conductive ITO substrate/a PEDOT:PSS layer/a tin perovskite layer/a C₆₀-BPy layer/a C₆₀ layer/a bathocuproine (BCP) layer/a metal counter electrode layer, see, for example, FIG. 5.

Specifically, in the above structure, ITO is used as a substrate layer for the device; PEDOT:PSS and C₆₀ are used as the hole transport layer (HTL) and electron transport layer (ETL), respectively; Tin perovskite is used as the light absorption layer; C₆₀-BPy is used as the interlayer between the perovskite layer and C₆₀.

### Manufacture of Tin-Based PVSC

An embodiment of the present invention relates to a process of preparing a tin-based inverted PVSC, which includes the steps of:
providing a substrate;
coating a hole transport layer onto the substrate; and
preparing a perovskite layer including the step of coating a perovskite precursor solution containing a tin-based perovskite composition onto the hole transport layer, in which the tin-based perovskite composition has the empirical formula: CsₓEDA_{y}FA_{1-x-2y}SnI₃, in which x is from about 0 to about 0.12; y is from about 0.01to about 0.03; FA is formamidinium; and EDA is ethylenediamine.

Without intending to be limited by theory it is believed that this process introduces EDA²⁺ ions, which can better stabilize the tin-based perovskite crystal structure and improve the stability of tin-based perovskite devices , and Cs+ can adjust the crystallization rate of perovskites for better processing, compared with traditional tin-based perovskite (CsₓFA₁₋ₓPbI₃).

In some embodiments, the substrate is subjected to the following treatment before coating the hole transport layer thereon: the substrate is sequentially cleaned by sonication with detergent, deionized water, acetone and isopropyl alcohol for about 10 min to about 30 min, respectively. Then, the substrate is dried at about 80° C. to about 120° C. in an oven, and then is treated with oxygen plasma for about 5 min to about 20 min and finally transferred into a N₂-filled glovebox before use. The substrate may be an ITO substrate having a surface resistivity of from about 10 Ωsq⁻¹ to about 45 Ωsq⁻¹, preferably about 15 Ωsq⁻¹. Without intending to be limited by theory it is believed that the surface resistivity of the substrate is negatively correlated with the transmittance of the substrate. If the resistance is too large, then the charge transfer will be affected. If the resistance is too small, the light transmittance of the substrate is poor, reducing the device efficiency.

In some embodiment, HTL materials (for example PEDOT:PSS) is filtered through a 0.45 μm filter and spin-coated on the substrate at from about 3500 rpm to about 4500 rpm (preferably about 4000 rpm) for about 50 s to 60 s (preferably 60 s), and then annealed at from about 100° C. to about 130° C. (preferably about 110° C.) for about 10 min to about 20 min (preferably 15 min). It is believed that, under such conditions, the HTL layer will be produced with uniform and dense surface.

In some embodiments, the process of preparing the tin-based inverted PVSC according to the invention further includes the step of:
preparing a surface treatment layer by coating a solution containing a functionalized fullerene derivative onto the perovskite layer, in which the functionalized fullerene derivative has a structure of formula I below:

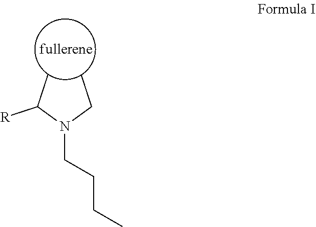

in which R is a monocyclic or poly cyclic aromatic ring comprising one or two nitrogen atoms.

In some embodiments, the process of preparing the tin-based inverted PVSC according to the invention further includes the steps of:
coating an electron transport layer onto the surface treatment layer, and
coating a metal electrode onto the electron transport layer.

In some embodiments, the step of preparing the perovskite layer includes:
preparing the perovskite precursor solution by mixing SnI₂, FAI, CsI and EDADI in DMF:DMSO (about 3:1/v:v to about 5:1/v:v, preferably about 4:1/v:v) mixed solvent with the empirical formula of CsₓEDA_{y}FA_{1-x-2y}SnI₃;
stirring the perovskite precursor solution at room temperature;
coating the perovskite precursor solution onto the hole transport layer after cooling it down to from about 0° C. to about 5° C. (preferably about 0° C.); and
annealing at from about 90° C. to about 160° C. (preferably about 110° C.) for about 7 min to about 50 min (preferably about 30 min).

The difference in the boiling points of the two solvents (DMF:DMSO) is used to control the solvent ratio, which is believed to have influence on the volatilization rate of the precursor, and control the crystallization rate of the perovskite. It is believed that cooling down to from about 0° C. to about 5° C. may reduce the rate of solvent evaporation in the solution, and the annealing step above makes perovskite crystals more complete, with uniform and dense surfaces.

In some embodiments, prior to stirring the perovskite precursor solution, the solution is added with about 10 mol % to about 15 mol % of excess SnF₂ and about 20 mg to about 30 mg Sn powder to suppress the Sn oxidation. In some embodiments, the perovskite precursor solution is stirred for about 6 h to about 10 h.

In some embodiments, the perovskite precursor solution is spin-coated at a rate from about 350 rpm to about 1800 rpm (preferably about 1250 rpm) for about 5 s to about 20 s (preferably about 10 s), subsequently at a rate from about 3500 rpm to about 7000 rpm (preferably about 5500 rpm) for about 30 s to about 60 s (preferably about 40 s). In some embodiments, about 30 μL to about 100 μL (preferably about 60 μL) perovskite precursor solution is spin coated under this condition. In some embodiments, the perovskite precursor solution has a concentration of from about 0.85 M to about 1.0 M (preferably 0.9725 M). In some embodiments, before the end of coating the the perovskite precursor solution, about 150 μL to about 300 μL (preferably about 200 μL) anti-solvent chlorobenzene is slowly dripped onto the center of perovskite film during about 5 s to about 18 s (preferably about 9 s). The as-prepared perovskite films are subsequently annealed on a hotplate at from about 90° C. to about 160° C. (preferably about 110° C.) for about 7 min to about 50 min (preferably about 30 min). It is believed that the perovskite layer prepared under such conditions will form more complete perovskite crystals, and the layer may have a uniform and dense surface.

In some embodiments, the step of preparing the surface treatment layer comprises:
preparing the solution comprising the functionalized fullerene derivative at a concentration from about 0.5 mg mL⁻¹ to about 2.0 mg mL⁻¹ (preferably about 1.0 mg/mL);
spin-coating the solution comprising the functionalized fullerene derivative onto the perovskite layer at from about 2500 rpm to 5500 rpm (preferably about 4000 rpm) for about 18 s to 30 s (preferably 30 s); and
annealing at from about 85° C. to about 135° C. (preferably about 110° C.) for about 1 min to about 10 min.

Without intending to be limited by theory it is believed that the surface treatment layer prepared under such conditions will have a uniform and dense surface.

In some embodiments, the functionalized fullerene derivative contained in the surface treatment layer has a structure selected from the group of:

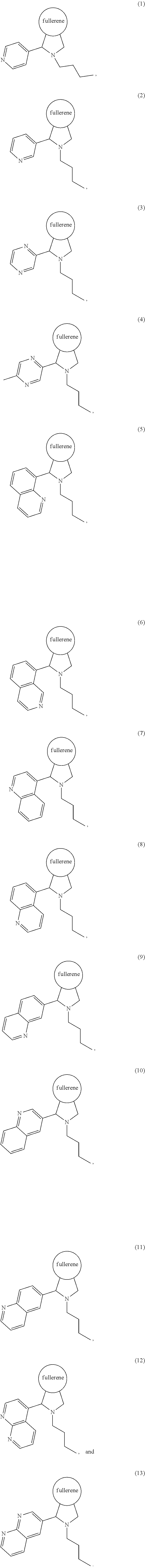

For the C₆₀-BPy interface modified devices, C₆₀-BPy powder is prepared and dissolved in chlorobenzene at a concentration of from about 0.5 mg mL⁻¹ to about 2.0 mg mL⁻¹. The as-prepared solution is stirred at room temperature (from about 20˜25° C.) until the solution became clear. The solution is then transferred to a N₂-filled glovebox before use. About 50˜120 μL C₆₀-BPy solution is spin-coated on top of the perovskite layer at from about 4000˜6000 rpm for about 10˜25 s, and next transferred to the hotplate and annealed at from about 60˜80° C. for about 2˜5 min. The spin-coating processes are all conducted at room temperature (from about 20˜25° C.) in a N₂-filled glovebox with the contents of O₂ and H₂O<2 ppm.

In some embodiments, after the surface treatment layer is coated, about 10˜30 nm C₆₀ with an evaporating rate of from about 0.3˜1.5 A s -1 , about 4˜10 nm BCP at a rate of from about 0.2˜1.2 Ås⁻¹ and about 70˜120 nm silver electrode at a rate of from about 0.5˜3.0 Ås⁻¹ are thermally evaporated, respectively, under high vacuum (<4×10⁻⁶ Torr).

In certain embodiments, the above-mentioned definitions and descriptions regarding the substrate, the hole transport layer, the electron transport layer, and the electrode also apply to the process herein.

### EXAMPLES

### Materials and Methods

The chemicals used include the following: Tin iodide (SnI₂, 99.999%) and Tin fluoride (SnF₂, 99%) are purchased from Alfa Aesar (Thermo Fisher Scientific, Lancashire, United Kingdom, https://www.alfa.com/zh-cn/regions/). Formamidinium iodide (FAI), Ethylenediamine iodine (EDADI), C₆₀, bathocuproine (BCP), and poly(3,4-ethylenedioxythiophene) polystyrene sulfonate (PEDOT:PSS) are purchased from Xi'an Polymer Light Technology Corporation (China, http://www.p-oled.cn/). Tin powder, Dimethyl sulfoxide (DMSO, anhydrous, 99.9%), Dimethyl formamide (DMF, anhydrous, 99.9%), and Chlorobenzene (CB, anhydrous, 99.8%) are purchased from TCI (TCI Worldwide Headquarters-TOKYO CHEMICAL INDUSTRY CO., LTD., Chuo-ku, Tokyo, https://www.tcichemicals.com/HK/en/). All these materials in experiments are used as received without any further purification.

The materials and device performance are characterized according to the following methods.

The ultraviolet-visible (UV-vis.) absorptions are measured by a UV-vis. spectrometer (PerkinElmermodel Lambda 2S, SpectraLab Scientific Inc., Markham, Canada, https://www.spectralabsci.com/equipment/perkin-elmer-uv-vis-spectrometer-lambda-2s/). UV-vis measurement is performed at room temperature with humidity 40-50%. The perovskite thin film samples are deposited on 1.5 cm×1.5 cm ITO for testing. A wavelength ranging from 300 to 900 nm is applied.

The surface-view morphologies are characterized by SEM (QUATTROS, Thermal Fisher Scientific, Waltham, USA, https://www.thermofisher.com/order/catalog/product/QUATTROESEM). SEM measurement is performed at vacuum with pressure lower than 2 torr. The perovskite thin film samples are deposited on ITO and cut to 0.5 cm×0.5 cm for testing. No gold spray treatment is carried out before the measurement. An Electron beam with 10 kV is applied.

The XPS spectra and the FTIR spectra are characterized by AXIS Supra XPS system (Kratos Analytical, Manchester, UK, https://www.kratos.com/products/axis-supra-xps-surface-analysis-instrument) and Thermo Scientific Nicolet iS 50 (Thermo Fisher Scientific, Waltham, MA USA, https://www.thermofisher.com/order/catalog/product/912A0760), repectively. XPS measurement is performed at vacuum with pressure lower than 2 torr. The perovskite thin film samples are deposited on ITO and cut to 0.5 cm×0.5 cm for testing. Monochromatic Al target test, energy 1486.6 eV, full spectrum pass energy 100 eV, step size 1.0 eV, narrow spectrum pass energy 30 eV, step size 0.05 eV, beam spot is 500 um.

Bruker Dimension Kelvin probe force microscopy in Potential Channel equipped with PFQNE-AL probe (Innovative Solutions Bulgaria Ltd., Sofia, Bulgaria, https://www.opustips.com/en/afm-tips.html?gclid=CjOKCQjw4omaBhDqARIsADXULuW8RulE43f0VoLRNidM0XoAo5mE0Yb6aagypbf6dkX9sr0Y1S_IcaAaAkoyEALw_wcB) is used to measure the surface potentials of perovskite films. Kelvin probe force microscopy is performed at room temperature with humidity 40-50%. The perovskite thin film samples are deposited on 1.5 cm×1.5 cm ITO for testing.

FLS980 (Edinburgh Instruments Ltd., Livingston, USA, https://www.edinst.com/products/fls-980-fluorescence-spectrometer/) is used to obtain steady-state and time-resolved PL spectra with an excitation wavelength of 485 nm. For FLS 980, the perovskite thin films are deposited on 1.5 cm×1.5 cm quartz glass sheet, and the measurement is performed at room temperature with humidity 40-50%.

Space Charge Limit Current Model (SCLC) is performed on electron-only (ITO/TiO₂/perovskite/C₆₀-BPy/C₆₀/BCP/Ag) and hole-only (ITO/PEDOT:PSS/perovskite/MoO₃/Ag, and measured from 0 to 6 V with a 0.02 V step size under dark conditions using a Keithley 2400 source/meter unit (Tektronix, Beaverton, USA, https://www.tek.com/en/products/keithley/source-measure-units/2400-standard-series-sourcemeter). The measurement is performed at room temperature in N₂ atmosphere.

Under simulated AM 1.5 G in N₂ glovebox at room temperature, the J-V curves of perovskite devices are recorded using a Keithley 2400 source meter, and the EQE spectra are carried out by a QE-R EQE system (EnLi Technology, Kaohsiung City, Taiwan, https://enlitechnology.com/home/products/eqe-photon-electron-conversion-testing/qe-r/). The active area is defined as 0.105 cm² and the light intensity is calibrated using a standard KG2 Si diode. All the devices are measured under a sweep mode of reverse scan (from 1.20 V to −0.01 V) and forward scan (from −0.01 V to 1.20 V) with the scan rate of 0.01 V s−1, and the delay time is 10 ms.

### Example 1

### Preparation of Functionalized Fullerene Derivatives

To a solution of C₆₀ (0.2 mmol) in chlorobenzene (25 mL), N-butyl glycine (52.5 mg, 0.4 mmol) and 4-pyridinecarboxaldehyde are added. Then, the mixture is heated at 80° C. under a nitrogen atmosphere for 5 h and monitored by thin layer chromatography. After cooling to room temperature, the solution is removed under reduced pressure. The resulted product purified via silica gel column chromatography affords 62 mg (34.6%) of C₆₀-BPy. 1H NMR (400 MHz, CDCl3) δ8.65 (d, J=5.1 Hz, 2H), 7.74 (s, 2H), 5.12 (d, J=9.5 Hz, 1H), 5.04 (s, 1H), 4.13 (d, J=9.4 Hz, 1H), 3.17 (dt, J=11.9, 8.3 Hz, 1H), 2.59 (ddd, J=12.1, 8.3, 4.2 Hz, 1H), 1.91-1.46 (m, 4H), 1.08 (t, J=7.3 Hz, 3H). 13C NMR (101 MHz, CDCl3/CS2) δ155.94, 153.75, 152.58, 152.15, 150.22, 147.39, 146.71, 146.41, 146.37, 146.29, 146.25, 146.20, 146.05, 146.03, 145.74, 145.72, 145.65, 145.52, 145.47, 145.43, 145.39, 145.38, 145.33, 145.30, 145.27, 144.79, 144.65, 144.49, 144.40, 143.25, 143.12, 142.81, 142.72, 142.69, 142.66, 142.33, 142.28, 142.22, 142.15, 142.11, 142.05, 141.93, 141.88, 141.78, 141.65, 140.37, 140.08, 139.61, 137.13, 136.43, 136.10, 135.64, 124.32, 81.55, 75.92, 68.98, 66.92, 53.25, 30.85, 21.13, 14.57. MALDI-TOF m/z: calculated for C₇₁H₁₆N₂[M]+896.71; found 896.41.

The synthesis of the fullerene derivatives having the structures (2) to (13) described above, a similar process is utilized, in which 4-pyridinecarboxaldehyde used for the synthesis of C₆₀-BPy is replaced by nicotinaldehyde, pyrazine-2-carbaldehyde, 5-methylpyrazine-2-carbaldehyde, quinoline-8-carbaldehyde, isoquinoline-8-carbaldehyde, quinoline-4-carbaldehyde, quinoline-5-carbaldehyde, quinoline-7-carbaldehyde, quinoline-3-carbaldehyde, quinoline-6-carbaldehyde, 1,8-naphthyridine-4-carbaldehyde, and 1,8-naphthyridine-3-carbaldehyde, respectively. Besides, other raw materials and synthesis methods remain unchanged.

### Example 2

### Perovskite Solar Cells

### 1. Preparation of PVSCs

The fabrication method of the tin PVSCs is as follows.

The ITO substrates are sequentially cleaned by sonication with detergent, deionized water, acetone and isopropyl alcohol for about 20 min, respectively. The ITO substrates have a surface resistivity of 15 Ωsq⁻¹. Then, the substrates are dried at about 110° C. in an oven, and then are treated with oxygen plasma for about 15 min and finally transferred into a N₂-filled glovebox before use.

Next, for the preparation of HTL, PEDOT:PSS aqueous solution is filtered through a 0.45 μm filter and spin-coated on the substrate surface at from about 3500 rpm to about 4000 rpm for about 50 s to 60 s, and then annealed at from about 110° C. for about 15 min to about 20 min.

Then, suitable perovskite materials are coated on the HTL. The optimized tin perovskite FA_{0.96}EDA_{0.02}SnI₃ is employed as the light active layer to fabricated PVSCs. For the preparation of FA_{0.96}EDA_{0.02}SnI₃, about 0.9725 M perovskite precursor solution is prepared by mixing SnI₂, FAI and EDADI in 1 mL DMF:DMSO (about 4:1/v:v) mixed solvent with a formula of FA_{0.96}EDA_{0.02}SnI₃, about 12 mol % of excess SnF₂ and about 24 mg Sn powder is needed to suppress the Sn oxidation. The solution is stirred at room temperature for about 6˜10 hours and is filtered through a 0.45 μm filter before use. Before spin-coating the perovskite solation, the solution is cooled down to from about 0˜5° C. for about 5˜10 min. Then, about 60 μL perovskite solutions are spin-coated onto the ITO/HTL at from about 1200 rpm for about 5˜20 s, subsequently at from about 5500 rpm for about 40 s. About 200 μL anti-solvent chlorobenzene is slowly dripped onto the center of perovskite film at about 9 s before the end of spin-coating. The as-prepared perovskite films are subsequently annealed on a hotplate at from about 110° C. for about 30 min.

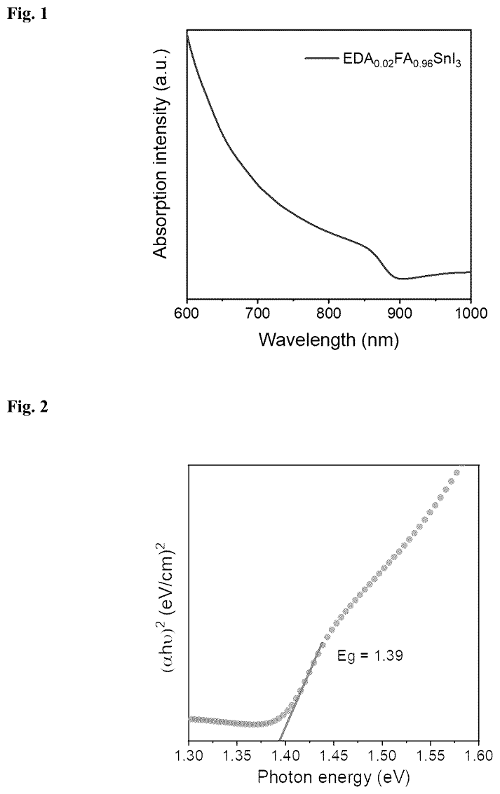

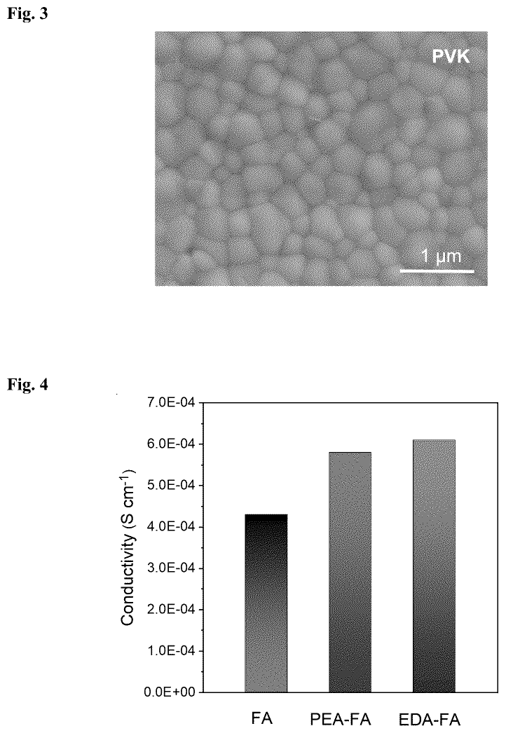

The ultraviolet-visible (UV-vis) absorption spectroscopy and corresponding Tauc plot of FA_{0.96}EDA_{0.02}SnI₃ are shown in FIGS. 1 and 2, respectively, indicating the optimized tin perovskite has a bandgap of 1.39 eV. FIG. 3 shows the SEM of FA_{0.96}EDA_{0.02}SnI₃ perovskite film. The carrier mobility of FA_{0.96}EDA_{0.02}SnI₃ is shown in FIG. 4, suggesting that the mobility of FA_{0.96}EDA_{0.02}SnI₃ is higher than other widely used tin perovskites (FASnI₃ and PEA_{0.15}FA_{0.85}SnI₃), and indicating FA_{0.96}EDA_{0.02}SnI₃ has strong carrier transport capability.

For the C₆₀-BPy interface modified devices, C₆₀-BPy powder is prepared and dissolved in chlorobenzene at a concentration of from about 1.0 mg mL⁻¹. The as-prepared solution is stirred at room temperature (from about 20˜25° C.) until the solution became clear. The solution is then transferred to a N₂-filled glovebox before use. About 60 μL C₆₀-BPy solution is spin-coated on top of the as-prepared perovskite layer at from about 5000 rpm for about 20 s, and next transferred to the hotplate and annealed at from about 75° C. for about 3 min. The spin-coating processes are all conducted at room temperature (from about 20˜25° C.) in a N₂-filled glovebox with the contents of O₂ and H₂O<2 ppm.

Next, about 25 nm C₆₀ with an evaporating rate of from about 0.5 Ås⁻¹, about 6 nm BCP at a rate of from about 0.3 Ås⁻¹ and about 100 nm silver electrode at a rate of from about 2.0 Ås⁻¹ are thermally evaporated, respectively, under high vacuum (<4×10⁻⁶ Torr).

In the device configuration as depicted in FIG. 5, PEDOT:PSS and C₆₀ are used as the HTL and ETL, respectively. Tin perovskite is used as the light absorption layer; and C₆₀-BPy is used as the interlayer between the perovskite layer and C₆₀ layer.

2. Effects of C₆₀-BPy modification

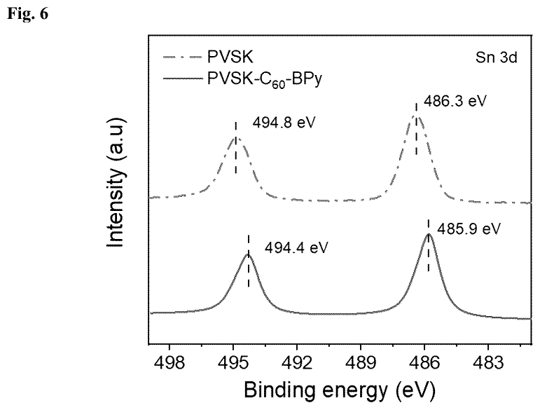

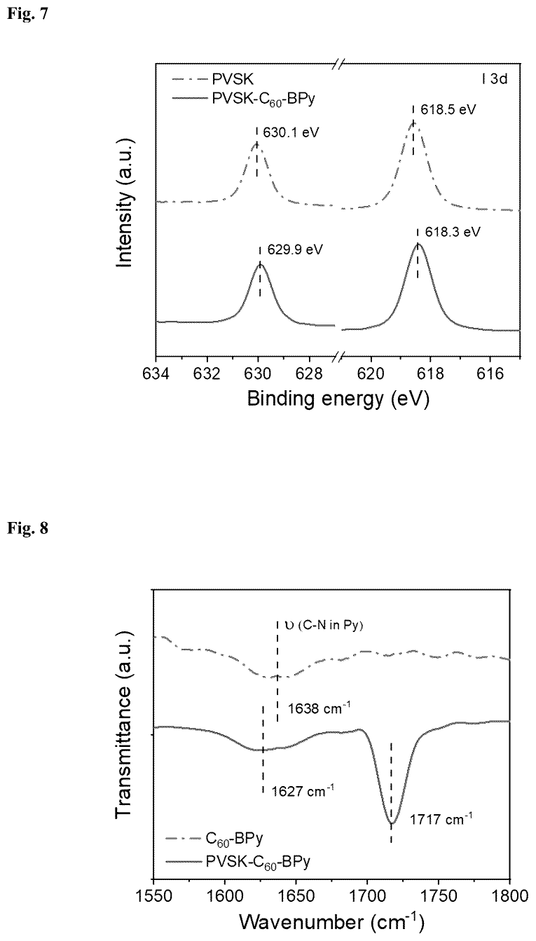

X-ray photoelectron spectroscopy (XPS) is used to track the changes in the binding energy of the perovskite films with and without C₆₀-BPy modification (i.e., after and before the step of depositing the C₆₀-BPy interface layer as described above). In FIG. 6 and FIG. 7, the binding energies corresponding to the Sn 3d and I 3d core levels of the C₆₀-BPy treated perovskite films shift marginally to lower values as compared to the control sample, indicating improved binding of both anions and cations on the perovskite surface, which may be related to the strong binding between the perovskite surface ions and C₆₀-BPy.

Fourier transform infrared spectroscopy (FTIR) is further performed to study the change of the characteristic peaks for C₆₀-BPy molecule before and after depositing on perovskite films (FIG. 8). The C—N bond in the pyridine group displayed stretching vibration at 1638 cm⁻¹ for pristine C₆₀-BPy, whereas shifted to 1627 cm⁻¹ for C₆₀-BPy modified perovskite films. Except for the C—N vibration, there is no discernible change in the other characteristic peaks.

The XPS and FTIR results confirm that the pyridine unit in C₆₀-BPy as a Lewis base is able to combine with Sn ions in perovskite with a formation of Sn—N bonding.

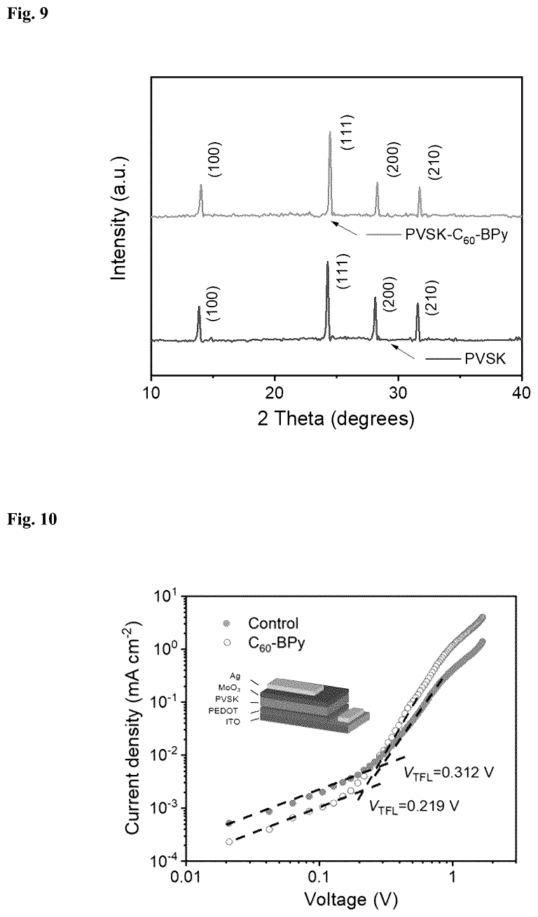

In addition, the XRD patterns in FIG. 9 indicate that the crystal structure of the perovskite film does not change after C₆₀-BPy modification, which shows no reaction of producing any impurity.

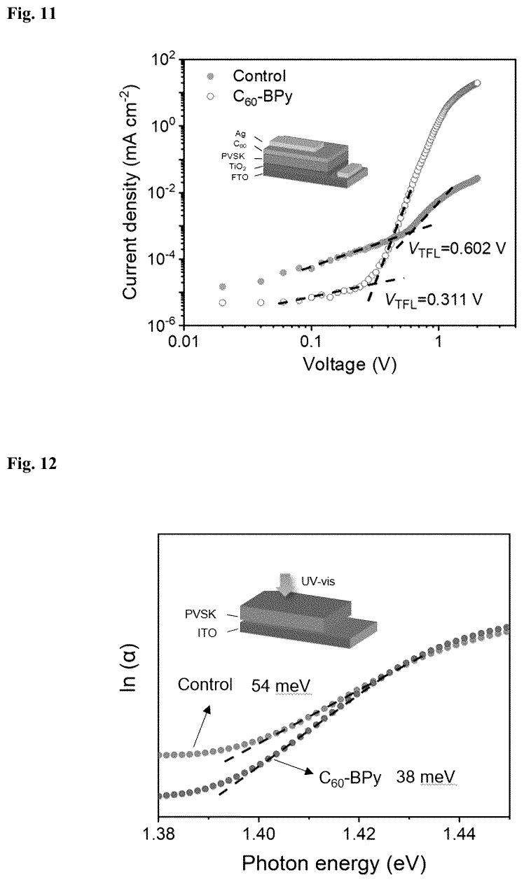

To investigate the effect of C₆₀-BPy on the trap-states at perovskite/ETL interface, the space-charge-limited-current (SCLC) measurements is conducted based on hole-only device (ITO/PEDOT:PSS/FA_{0.96}EDA_{0.02}SnI₃/MoO_{3/}Ag) and electron-only device (ITO/TiO₂/FA_{0.96}EDA_{0.02}SnI₃/C₆₀/Ag) as shown in FIG. 10 and FIG. 11. The method for preparing these two types of devices are known to the skilled persons. For example, references can be made to Zhen Li, et al., Organometallic-functionalized interfaces for highly efficient inverted perovskite solar cells, Science, Vol. 376, Issue 6591, pp. 416-420, 2022). The equation of V_{TFL}=eNₜL²/2εε₀ can be used to compute the trap density (Nₜ), where L is the perovskite film thickness, ε is the relative dielectric constant, ε₀is the vacuum permittivity, and V_{TFL} is the trap-filling voltage. After C₆₀-BPy modification, the hole trap density decreases from about 5.93×10¹⁵ cm⁻³ to about 4.16×10¹⁵ cm⁻³, and the electron trap density reduces from about 1.14×10¹⁶ cm⁻³ to about 5.91×10¹⁵ cm⁻³. The reduced hole and electron trap densities demonstrate that the defects at the perovskite/ETL interface of the devices have been suppressed via the modification of C₆₀-BPy.

The Urbach energy, which is the energetic disorder at the band edge, is further calculated using the formula α=α₀exp(E/Eu), where a is the absorption coefficient, E is the photon energy, and Eu is the Urbach energy. As illustrated in FIG. 12, the FA_{0.96}EDA_{0.02}SnI₃ perovskite film modified with C₆₀-BPy exhibits a sharper band edge than the pristine one.

Moreover, the Eu is about 54 meV for the control sample, while reduces to about 38 meV for the C₆₀-BPy modified film, which originates from the lower band edge energy disorder and trap density.

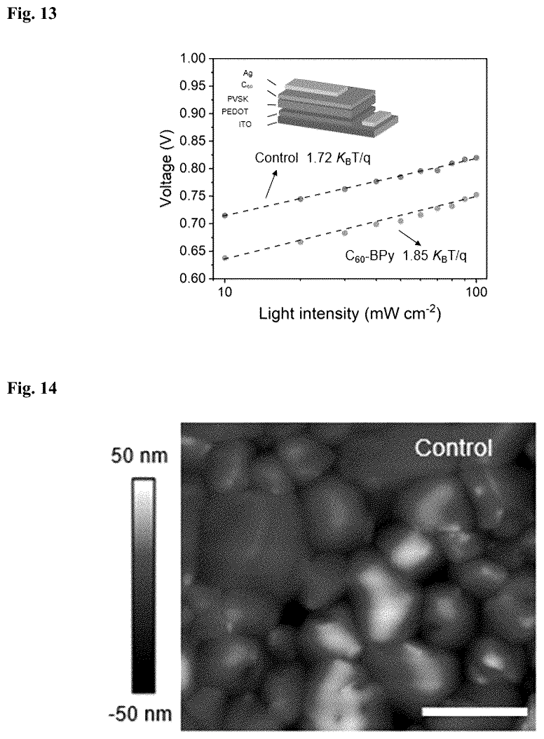

To further elucidate the interface functionalization and understand the relationship between trap-state and charge recombination, light intensity dependent voltage measurements are performed as shown in FIG. 13. The correlation between Voc and light intensity (I) is V_{OC}=(nkT/e)ln(I/I₀+1), where n is the ideality factor, k is the Boltzmamm constant, and T is the temperature. The slope of the fitted curve is connected with the ideality factor (n) in the form of nkBT/q, which can be used to assess trap-assisted Shockley-Read-Hall (SRH) recombination in PVSCs. The n value reduces from 1.85 to 1.72 as introducing the C₆₀-BPy interlayer, indicating that trap-assisted SRH recombination is inhibited.

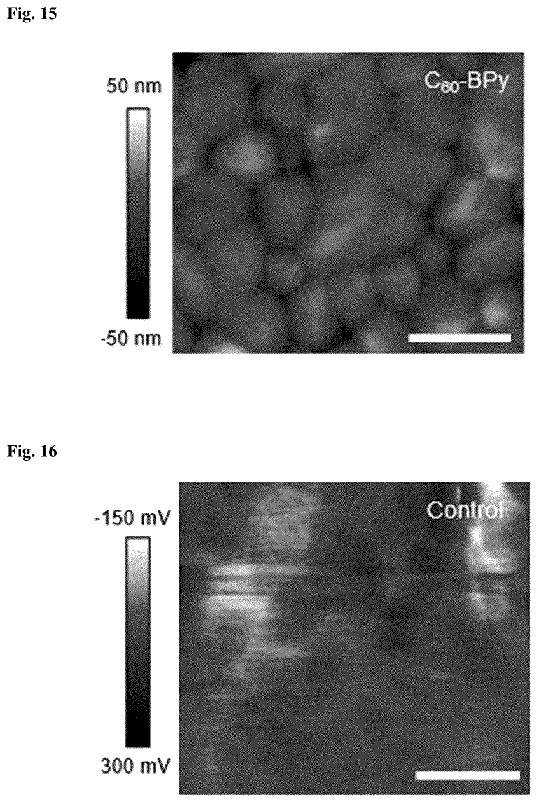

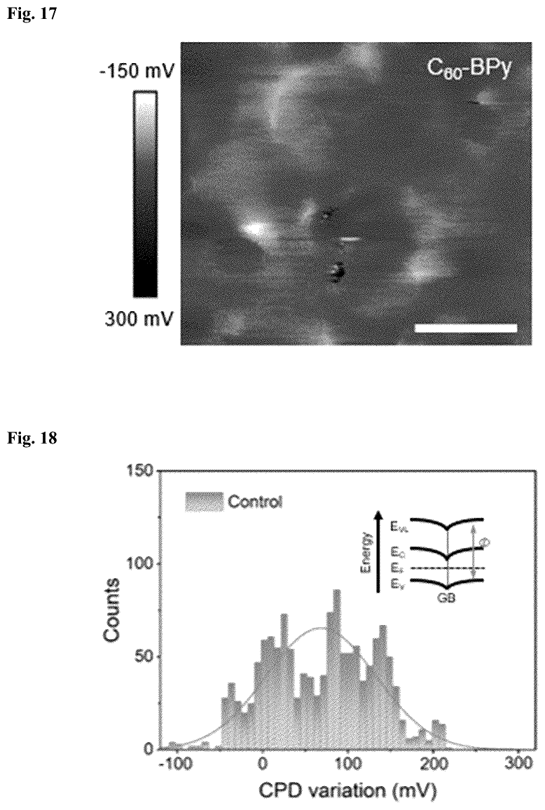

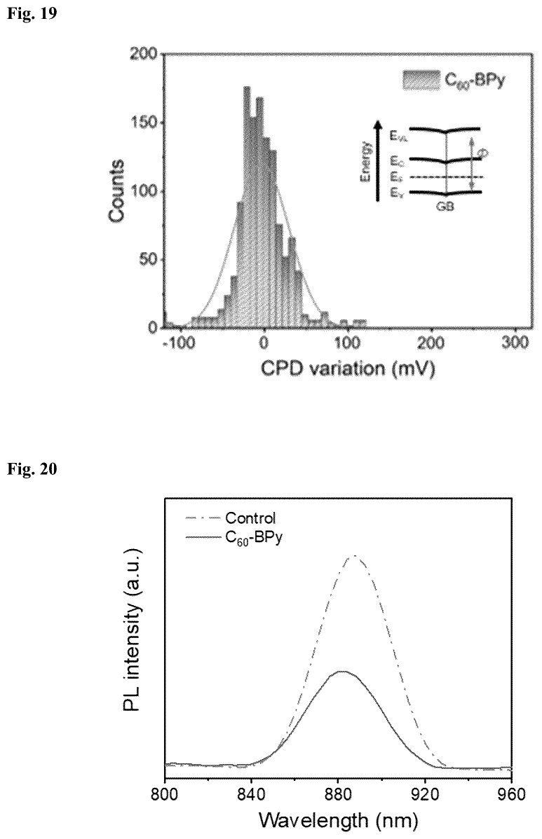

FIG. 14 and FIG. 15 show the Atom force microscopy (AFM) of the control and the C₆₀-BPy treated perovskite films. The perovskite grain size and morphology do not change when the C₆₀-BPy interlayer is deposited. However, the surface contact potential of the C₆₀-BPy functionalized perovskite film exhibits a decreased average value (−100 mV) relative to that of the control sample as shown in FIG. 16 to FIG. 19. The inventors attribute the reduced contact potential to the surface charge transfer induced by the interaction between C₆₀-BPy and perovskite. Moreover, the C₆₀-BPy functionalized perovskite displays a smaller potential distribution and surface potential difference (−200 mV) than that of the control sample (−350 mV). A uniform distribution of surface contact potential is believed to be beneficial for effective charge carrier extraction and non-radiative recombination inhibition at perovskite grain boundaries.

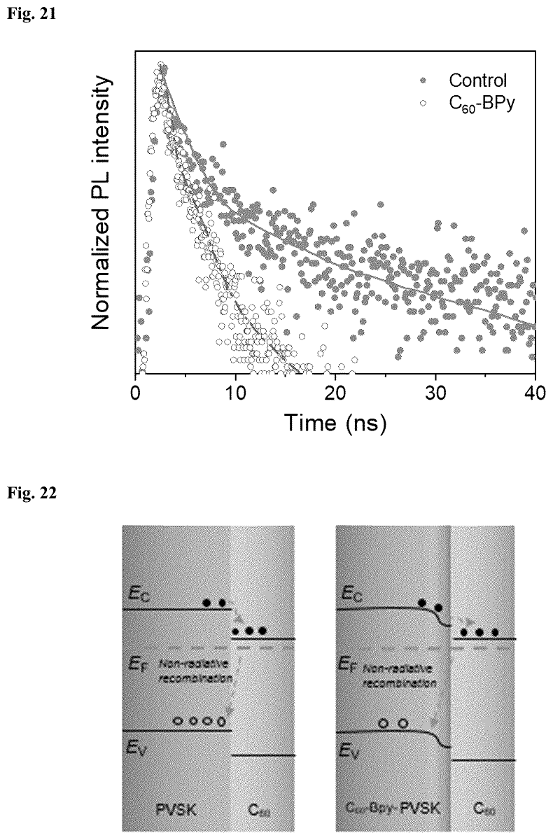

The steady-state photoluminescence (PL) and time-resolved photoluminescence (TRPL) are conducted (FIG. 20 and FIG. 21) to further study the charge carrier kinetics at the perovskite/ETL interface (with a structure of glass/FA_{0.96}EDA_{0.02}SnI₃/C₆₀). The C₆₀-BPy treated perovskite film shows an obvious decreased intensity compared to the control sample. Moreover, the carrier lifetime of C₆₀-BPy treated films obtained by fitting the TRPL spectra exhibits a reduction from about 8.67 ns to about 1.73 ns. The findings suggest that the C₆₀-BPy functionalization can boost electron extraction at the perovskite/ETL interface.

Accordingly, the energy level diagrams of the control and the C₆₀-BPy functionalized perovskite are displayed in FIG. 22. Compared to the control one, a more “n-type” nature for C₆₀-BPy functionalized interface is verified because of the upshifted Fermi level relative to the vacuum band. This optimal energy level alignment can not only allow photogenerated electron to be extracted by the ETL with reduced energy loss, but also bounce back electrons at the interface.

3. Performances of C₆₀-BPy modified photovoltaic devices

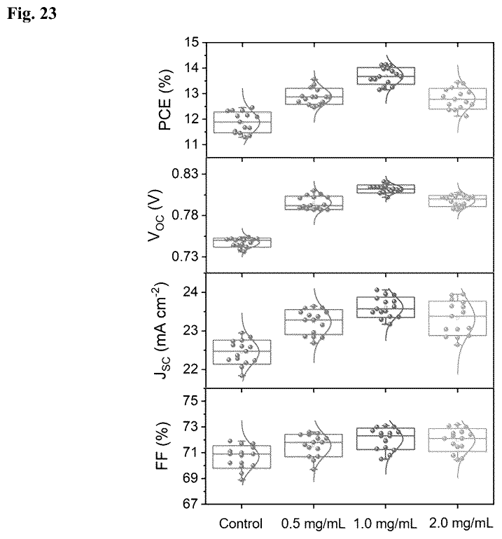

The PVSCs are prepared with the method described above, with the only difference that different concentrations of C₆₀-BPy (about 0 mg/mL, about 0.5 mg/mL, about 1.0 mg/mL, about 2.0 mg/mL) are used for producing the C₆₀-BPy interlayer. To verify the effect of C₆₀-BPy interlayer on photovoltaic performance, the J-V measurements are conducted on the tin PVSCs modified with different concentrations of C₆₀-BPy as shown in FIG. 23. The J-V characteristics of photovoltaic devices is conducted in a N₂-filled glovebox at room temperature by using a Xenon lamp solar simulator (Enlitech, SS-F5, Taiwan). The power of the light is calibrated to 100 mW cm−2 by a silicon reference cell (with a KG2 filter). All the devices are measured using a Keithley 2400 source meter under a sweep mode of reverse scan (from 1.20 V to −0.01 V) and forward scan (from −0.01 V to 1.20 V) with the scan rate of 0.01 V s−1, and the delay time is 10 ms. The results indicate that each solar cell parameter improves when compared to the control device, and that the average PCE exhibits a tendency of growing initially and then dropping as the concentration of C₆₀-BPy increases.

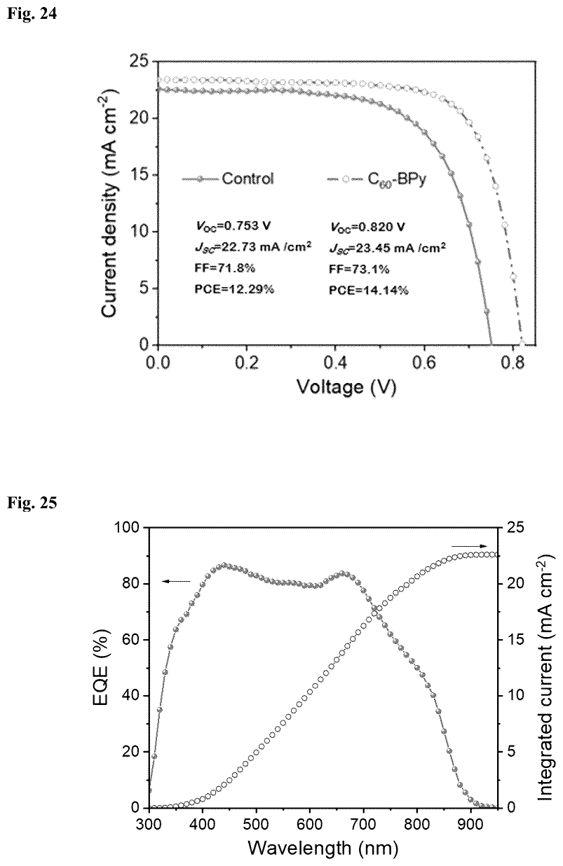

In FIG. 24, the control PVSC exhibits a maximum PCE of about 12.29%, with an open-circuit voltage (V_{OC}) of about 0.753 V, a short-circuit current density (J_{SC}) of about 22.73 mA cm⁻² and a fill factor (FF) of about 71.8%. As compared to the control device, the C₆₀-BPy interlayer (about 1.0 mg mL⁻¹) functionalized device shows an enhanced PCE of about 14.14%, with a V_{OC} of about 0.820 V, a Jsc of about 23.45 mA/cm² and an FF of about 73.1%.

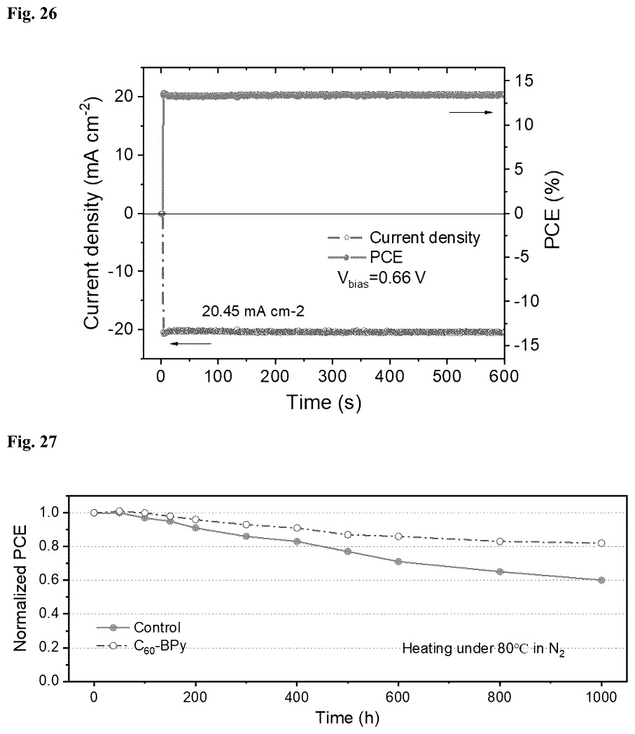

The corresponding external quantum efficiency (EQE) of the champion device (a concentration of C₆₀-BPy of about 1.0 mg mL⁻¹) in FIG. 25 produces integrated J_{SC} with a minor difference from the value obtained from the J-V measurements. The C₆₀-BPy functionalized device is also measured at the maximum power point (MPP) to obtain a stabilized photocurrent of about 20.45 mA cm⁻² and a stabilized PCE of about 13.50%. (FIG. 26).

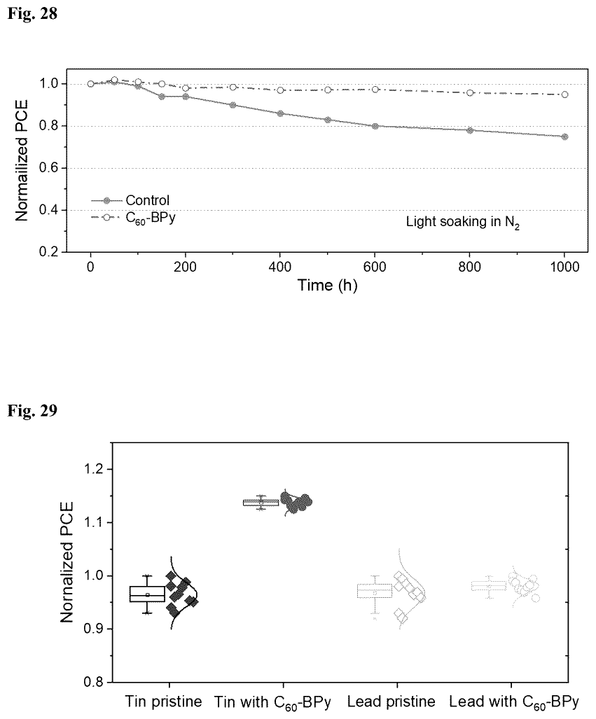

To investigate the stability of the tin PVSCs with the C₆₀-BPy interface modification (about 1.0 mg mL⁻¹), the PCE of the unencapsulated devices is recorded under the continuous illumination condition (AM 1.5 G simulated solar light) and heating condition (about 80° C.) and in N₂, respectively, and the PCE evolutions are depicted in FIG. 27 and FIG. 28. The C₆₀-BPy treated devices show excellent light stability with about 95.3% initial PCE retained after 1000 hours. In contrast, the PCE of the control devices degraded to about 75.2%. In addition, for the heating stability shown in FIG. 28, the C₆₀-BPy treated PVSC maintained>about 80% initial PCE after 1000 hours aging, while the PCE of the control device decayed to about 60%.

To demonstrate the unique effect of C₆₀-BPy interface modification on tin PVSCs, the inventors compare the efficiencies of tin and lead PVSCs treated with and without C₆₀-BPy. As can be seen from the comparison of normalized efficiencies in FIG. 29, the introduction of C₆₀-BPy can significantly improve the efficiency of tin PVSCs; on the contrary, the introduction of C₆₀-BPy into lead PVSCs only slightly improves the efficiency.

It should be understood that the above only illustrates and describes examples whereby the present invention may be carried out, and that modifications and/or alterations may be made thereto without departing from the spirit of the invention.

It should also be understood that certain features of the invention, which are, for clarity, described in the context of separate embodiments, may also be provided in combination in a single embodiment. Conversely, various features of the invention which are, for brevity, described in the context of a single embodiment, may also be provided separately, or in any suitable subcombination.

All references specifically cited herein are hereby incorporated by reference in their entireties. However, the citation or incorporation of such a reference is not necessarily an admission as to its appropriateness, citability, and/or availability as prior art to/against the present invention.

1. A lead-free tin-based perovskite solar cell (PVSC) comprising:
a surface treatment layer comprising a functionalized fullerene derivative having a structure of formula I below: 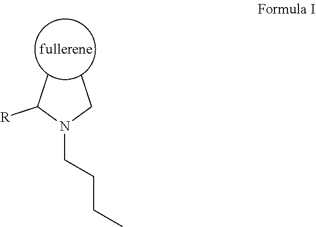
wherein R is a monocyclic or polycyclic aromatic ring comprising one or two nitrogen atoms; and
a perovskite layer comprising a tin-based perovskite composition having the empirical formula:
CsₓEDAₓFA_{1-x-2y}SnI₃
wherein x is from about 0 to about 0.12;
wherein y is from about 0.01 to about 0.03;
wherein FA is formamidinium; and
wherein EDA is ethylenediamine

2. The lead-free tin-based perovskite solar cell of claim 1, wherein R is a monocyclic aromatic ring selected from the group consisting of pyrazine, pyridine, and a combination thereof.

3. The lead-free tin-based perovskite solar cell of claim 1, wherein R is a polycyclic aromatic ring selected from the group consisting of isoquinoline, naphthyridine, and a combination thereof.

4. The lead-free tin-based perovskite solar cell of claim 1, wherein the functionalized fullerene derivative has a structure selected from the group consisting of:

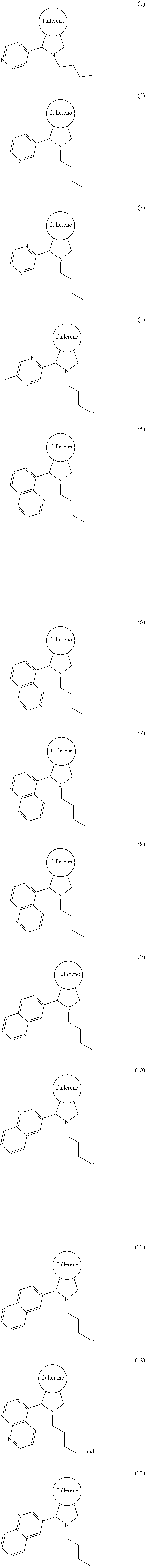

5. (canceled)

6. The lead-free tin-based PVSC of claim 1, wherein x is about 0, and y is about 0.02.

7. The lead-free tin-based PVSC of claim 1, wherein the surface treatment layer is in contact with one side of the perovskite layer.

8. The lead-free tin-based PVSC of claim 1 further comprising the following layers:
a substrate;
a hole transport layer between the substrate and the perovskite layer;
an electron transport layer on the surface treatment layer; and
a metal electrode on the electron transport layer.

9. The lead-free tin-based PVSC of claim 8, wherein the surface treatment layer is inserted between the perovskite layer and the electron transport layer.

10. The lead-free tin-based PVSCs of claim 8, wherein the substrate comprises a material selected from the group consisting of ITO/Glass, ITO/PEN, ITO/PET, FTO/Glass, FTO/PEN, FTO/PET, and a combination thereof.

11. The lead-free tin-based PVSCs of claim 8, wherein the hole transport layer comprises a material selected from the group consisting of PEDOT:PSS, PTAA, and a combination thereof.

12. The lead-free tin-based PVSCs of claim 8, wherein the electron transport layer comprises a material selected from the group consisting of fullerene C₆₀, TiO₂, SnO₂, Al₂O₃, PC₆₁BM, PC₇₂BM, and a combination thereof.

13. A process of preparing a tin-based PVSC comprising the steps of:
providing a substrate;
coating a hole transport layer onto the substrate; and
preparing a perovskite layer comprising the step of coating a perovskite precursor solution comprising a tin-based perovskite composition onto the hole transport layer, wherein the tin-based perovskite composition has the empirical formula: CsₓEDA_{y}FA_{1-x-2y}SnI₃;
wherein x is from about 0 to about 0.12;
wherein y is from about 0.01 to about0.03;
wherein FA is formamidinium; and
wherein EDA is ethylenediamine

14. The process of claim 13 further comprising the step of:
preparing a surface treatment layer by coating a solution comprising a functionalized fullerene derivative onto the perovskite layer, wherein the functionalized fullerene derivative has a structure of formula I below: 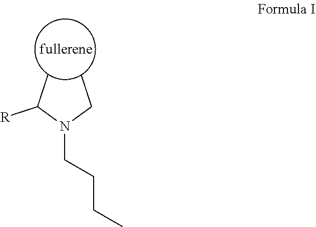
wherein R is a monocyclic or polycyclic aromatic ring comprising one or two nitrogen atoms.

15. The process of claim 14, further comprising:
coating an electron transport layer onto the surface treatment layer, and
coating a metal electrode onto the electron transport layer.

16. The process of claim 13, wherein the step of preparing the perovskite layer comprises:
preparing the perovskite precursor solution by mixing SnI₂, FAI, CsI and EDADI in DMF:DMSO (about 3:1/v:v to about 5:1/v:v) mixed solvent with the empirical formula of CsₓEDA_{y}FA_{1-x-2y}SnI₃;
stirring the perovskite precursor solution at room temperature;
coating the perovskite precursor solution onto the hole transport layer after cooling it down to from about 0° C. to about 5° C.; and
annealing at from about 90° C. to about 160° C. for about 7 min to about 50 min.

17. The process of claim 14, wherein the step of preparing the surface treatment layer comprises:
preparing the solution comprising the functionalized fullerene derivative at a concentration from about 0.5 mg mL⁻¹ to about 2.0 mg mL⁻¹;
spin-coating the solution comprising the functionalized fullerene derivative onto the perovskite layer at from about 2500 rpm to 5500 rpm for about 18 s to 30 s; and
annealing at from about 85° C. to about 135° C. for about 1 min to about 10 min.

18. The process of claim 14, wherein the functionalized fullerene derivative has a structure selected from the group consisting of:

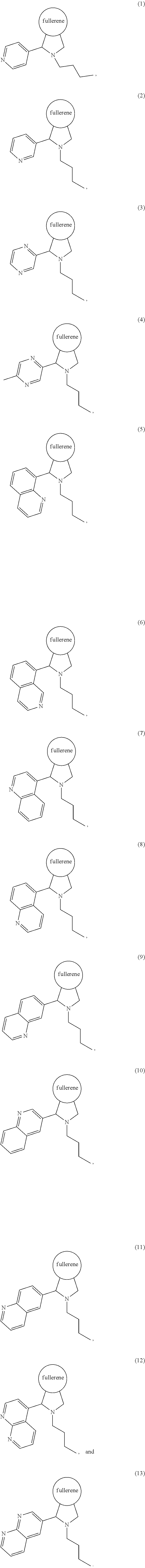

19. The process of claim 15, wherein the substrate comprises a material selected from the group consisting of ITO/Glass, ITO/PEN, ITO/PET, FTO/Glass, FTO/PEN, FTO/PET, and a combination thereof; the hole transport layer comprises a material selected from the group consisting of PEDOT:PSS, PTAA, and a combination thereof; and the electron transport layer comprises a material selected from the group consisting of C₆₀, TiO₂, SnO₂, Al₂O₃, PC₆₁BM, PC₇₂ BM, and a combination thereof.

20. The process of claim 16, wherein the perovskite precursor solution is spin-coated at a rate from about 350 rpm to about 1800 rpm for about 5 s to about 20 s, and subsequently at a rate from about 3500 rpm to about 7000 rpm for about 30 s to about 60 s.
